(19) United States
(12) Patent Application Publication
(10) Pub. No.: US 2009/0153187 A1
(43) Pub. Date: Jun. 18, 2009

(54) Monolithically integrated interface circuit

(75) Inventors: Reiner Bidenbach, Vörstetten (DE); Jörg Franke, Freiburg (DE); Burkhard Giebel, Denzlingen (DE); Markus Rogalla, Bad Krozingen (DE)

Correspondence Address: O''Shea Getz P.C., 1500 MAIN ST. SUITE 912, SPRINGFIELD, MA, 01115, US

(73) Assignee: Micronas GmbH, Hans-Bunte-Strasse 19 (DE)

(21) Appl. No.: 10/580,780

(22) PCT Filed: Nov. 24, 2004
(86) PCT No.: PCT/EP2004/013308

§ 371 Date: May 25, 2006

(30) Foreign Application Priority Data
Nov. 28, 2003 (DE) 10356314.8

(51) Int. Cl. H03K 19/173

(52) U.S. Cl. 326/38

(57) ABSTRACT

The invention relates to integrated circuits comprising a monolithically integrated logic IC and a monolithically integrated interface circuit that is conductively connected to the logic IC. The electrical properties of said interface circuit are programmable. The interface circuit also has a lower integration density than the logic IC, and comprises monitoring modules for monitoring the logic ICs.

The invention relates to monolithically integrated circuits, in particular, monolithically integrated processors which as a result of ongoing pattern¹ miniaturization are able to accommodate more and more functional units, and thus take on ever more complex automatic control functions. This trend is spurred by the fact that development and fabrication costs for stand-alone solutions are continually rising, with the result that stand-alone solutions are increasingly abandoned, while more-universal standardized circuits are offered which are, of course, even larger and more expensive, but which can be adapted to individual functions and applications through software-based programming. At the same time, entirely new problems are arising in connection with such “universal solutions” and these problems require a technical solution. A additional problem relates to the fact that with many areas of application the required availability of the individual circuits must be far greater than the change cycles determined by the technology. When the technology changes, as a rule many electronic parameters of the circuit also change and these must be taken into account in the peripheral circuits. Some of these problems are discussed below and appropriate solutions are indicated. An essential aspect in all of these solutions consists in the fact that a kind of decoupling occurs between the actual processor and the application level since critical terminals of the processor do not communicate with the peripherals directly but only through an interface circuit.

A general goal in the fabrication of semiconductors is to reduce production costs. Contributing to this goal are the reduction of pattern widths in semiconductor processors and the use of larger and larger wafers during fabrication. The resulting trend is that comparatively simple functions (example, 8-bit microcontroller) can be produced in ever greater numbers using a single water lot.

One problem that arises is that the individual product cannot be tested and accepted in these quantities, while at the same time the costs for the photolithographic masks, the reticle costs, must be allocated to the individual ICs at an ever-increasing level. The result is a trend reversal which ¹Translators note: With reference to integrated circuits, German Struktur can mean either the pattern or the feature provided by the pattern. The choice was made to translate it as “pattern.”

results in deterrence to any customer-specific tailor-made ICs in small production runs, known by the term “ASICs”.

### Solution to the Problem

According to the invention, the conflict between the minimum volume supplied and the maximum volume demanded is solved by partitioning the ASIC function into:

1. a core (“EngineUnit”)
which is the same for many comparable ASICs and for which there is thus a demand at high volume;
which can be shrunk without special requirements;
which can come from any desired semiconductor factory.
   2. a peripheral device (the described interface circuit—“BodyUnit”)
which implements the application-specific adaptation to the specific function, in other words, stands for the AS in ASIC;
which can be fabricated at low risk using less dense technologies at comparatively smaller minimum volumes and at lower specific mask expense due to the lower integration density requirement.

DE 101 57 457 A1 already discloses an approach to constructing an integrated circuit from a first IC (interconnect IC) composed of a plurality of voltage-tolerant connections and a bus interface, and a second IC (logic IC) having a plurality of logical circuits that supply data through a bus to a first IC. The interconnect IC and the logic IC here may have different integration densities. A disadvantageous aspect here, however, is that, according to the teaching of DE 101 57 457 A1, for a given required adaptation of the interconnect IC a complete redevelopment of this IC is required.

DE 102 43 684 describes a receiving device for a programmable electronic processing device that has a first and a second monolithic integrated component. The first component here comprises the input and output interfaces of the complete processing device. The second component is accessible only through the first component. The first component contains interface circuits that function to electrically adapt the terminals of the second component to external conditions. At least one of the interface circuits here can be programmable in terms of its electrical properties.

The above-described prior art documents do not, however, provide any solution to the problem of monitoring control in the event of a failure by a functional component, while at the same time also enabling the initially referenced conflict to be solved between the minimum volume offered and the maximum volume demanded.

The invention solves this problem by means of the features of claims 1 and 5, according to which specifically the interface circuit has monitoring modules to monitor the logic ICs. Advantageous embodiments of the invention are discussed in the subordinate claims and in the following description.

The result is, for example, an IC family which, with its overall high volume, provides the minimum volume of a high-density core, while also covering the demanded partial volume of the individual ASIC solution with an inexpensive interface for the peripherals.

### Problem of Declining Number of Semiconductor Fabrication Facilities

In order to further increase productivity in semiconductor fabrication, the pattern widths of the semiconductor processes are reduced while larger wafers are employed. As a result, however, the capital investment expense also grows at an increasing rate for new fabrication facilities. The semiconductor companies counter this trend by increasingly sharing the capital investment cost with other semiconductor companies. The result is fewer and fewer fabrication facilities of ever-greater capacity which an increasing number of companies share.

On the other hand, the buyers of semiconductors, the automotive sector in particular, must also constantly take care to ensure that they are able to procure every component from a second source. Adhering to this requirement becomes more and more difficult, however, since even if a specific component can be obtained from more than one semiconductor supplier, it increasingly comes from only one semiconductor fabrication facility.

A factor making this situation even more difficult is that in an automobile the service life of a given application is generally much longer than the generation cycle of the semiconductor fabrication or technology. As a result, the semiconductor buyer from the automotive industry must worry about finding a second source for each generational change of the semiconductor, that is, even more than once per service life of a given application.

### Solution to the Problem

The monolithically integrated interface circuit according to the invention, which in the following is generally termed “automotive package” based on its main area of application in the automotive sector, solves the conflict by a partitioning into:

3. said core (“EngineUnit”) which may be a highly-integrated standardized component (CPU+memory);
which however can be utilized through the “BodyUnit” in a wide variety of applications;
without special requirements can be transferred to new fabrication facilities and/or to new technologies;
which its predecessor can always replace without risk as a second source.
   4. said peripheral device (“BodyUnit”)
which implements the interface to the specific application;
   which can be fabricated using lower-density technologies due to the lower integration density required;
   which therefore does not always need to be transferred to new fabrication facilities and/or technologies;
   for the fabrication facility or technology of which a second source must therefore be arranged only once, and is more readily obtainable due to the low integration density.

### The Problem of the Withstand Voltage in the Case of a Change in Technology

Advantages of the automotive package include usability of increasingly smaller technologies for the logic chip (engine IC). If one retains the functionality in the case of a shrinking of the engine IC, a requalification of the externally accessible system is avoided since externally there is no noticeable change in the electrical or functional parameters. It is known that the operating voltage of the logic IC will also become increasingly smaller as the pattern sizes become smaller. In order to avoid leakage currents, damage to the engine IC, and malfunctions, modification of the signal level is absolutely necessary. To preclude a system requalification, however, the body IC to the greatest extent possible should not change.

Solution to the Problem through an Interface which is Programmable in Terms of Voltage

The voltage controller on the body IC that supplies the operating voltage for the logic IC (engine IC) is made programmable in terms of its voltage level. For example, this interface can be designed for a voltage swing of several 100 mV. The data required for this purpose are stored, for example, in an E²PROM or are specified by bonding options. The voltage range covers all conceivable supply voltage levels for future logic technologies.

There are two possible ways of adjusting the voltage levels of all the interface signals. If the voltage difference and/or the maximum frequency is small enough (for example, up to 2.5 V/10 MHz), then known CMOS level shifters are used for the engine-to-body signal path. They are dimensioned right from the start such that they will thus later function down to a previously defined minimum voltage. They thus cover a voltage range between, for example, 5 V and 2.5 V. If it is foreseeable that in the future even lower voltages will be utilized, or that a higher frequency bandwidth will be required, then analog comparators are employed. The switching threshold of these in turn is programmable, for example, through E²PROM.

The voltage level of the signals transferred from the body IC to the engine IC is also programmable. This is achieved by the fact that the output drivers of the body IC are operated at a supply voltage which is reduced and is programmable in terms of level.

Problem of the Area Requirement for the Bonding Pads in ICs with a High Number of Terminals—Avoiding the Pad Limit

If one wants to profit in terms of cost from the use of increasingly denser logic processes while retaining the same or disproportionately more slowly growing functionality, then one must avoid a situation in which the chip area is determined by the number of pads.

### Solution to the Problem

The number of pads of the engine IC must be minimized from the start. This is achieved by using a serial data transfer in place of parallel busses. In addition to address lines and data lines, it is also possible to route interrupts and other control lines through one or more serial interfaces.

Programmable Interface, wherein the Programmability Relates to Additional Parameters:

Advantages of the automotive package include the usability of increasingly smaller technologies for the logic chip (engine IC). If given a change in the engine IC the system function is retained externally, then requalification of the system is avoided.

A requalification of the system impends, however, whenever the new engine IC requires a modified bus interface configuration of the peripheral IC (BodyUnit), and the peripheral IC is modified for this purpose. This is because when the externally appearing peripheral IC is changed in terms of layout, this can cause a modified behavior in terms of ESD, latchup, EMC, etc.

In order to preclude the necessity of a new system qualification, however, the peripheral IC should thus not change if at all possible.

Solution to the Problem through Configurable Interface on Peripheral IC

In order to avoid a redesign of the peripheral IC (BodyUnit) in response to a change in the bus interface parameters on the core IC (EngineUnit), the logic of the bus interface on the peripheral IC is designed to be configurable so that if required it can be adapted to the interface of the core IC.

Configuration must occur on the peripheral IC since otherwise no communication can be established through the bus interface when the system is started up. The configuration parameters must be inherent in both component ICs.

The configuration can, however, also affect the data or signal flow between peripheral and core, for example, when certain terminals must be switched in order to be able to effect a simple matching between the predetermined peripheral IC and different core ICs. This may be of interest, for example, whenever essentially similar core ICs from different manufacturers are used which however have slight differences in terms of some pins or some inputs. It is conceivable, for example, that not all the available sites of a data bus required by the core IC are required for the intended application. Another difference may relate to special inputs for control and monitoring functions.

The configuration is effected, for example, by programming flash, EEPROM, OTP, fusible link elements, or by bonding options.

### Problem of Monitoring Control in the Event of a Failure by a Functional Component

In safety-relevant control devices, such as for example in an automobile, use is frequently made of a monitoring IC separate from the actual controller. While the functions of this IC, power or clock supervision, and/or watchdog could be easily co-integrated on the controller, given the background of a possible break in a single connection between the core and peripheral, or of the connection to another circuit (die)—for example, to a memory co-integrated in the package—the safety function for the entire system would be jeopardized.

The conventional remedy to this situation by using another die in a separate IC primarily has disadvantages in terms of cost:
an additional complete package is required;
to this end, space must be reserved and the circuit board and extra wiring work must be performed.

### Solution to the Problem

The automotive package solves the conflict by partitioning within a package into:
5. a core (EngineUnit) which contains the actual controller;
6. a peripheral (BodyUnit) on which all the monitoring modules such as power or clock supervision and/or watchdog are located which on a die separate from the controller are able to monitor the latter.
   Any breakage here of an individual die is thus not enough to shut off all of the safety functions since these are distributed over more than one die. Nevertheless, only one package is required.

### Problem of Bonding Pad Geometry

If, with a change in technology, the core IC is available only as a geometrically shrunk version of the predecessor IC—for example, when the IC comes from another manufacturer—the bonding pad geometry of the peripheral IC and of the core IC may be incompatible, with the result that crossed bonding leads are necessary or certain bond positions cannot even be reached. In order to ensure that wiring is nevertheless ensured using the normal bonding leads, a redistribution layer—for example, one or more additional metallization layers or layers composed of polyimide plus a metal layer—is deposited on the interface IC. The redistribution layer can also be used to compensate for varying bonding pad geometries of the core IC without modifying the wiring on the peripheral IC. This step may be required, for example, when the co-integrated JEDEC flash ICs are obtained from different suppliers. This measure also solves the problem of the second source supplier for the core IC when the relative positions of the bonding leads of the core ICs used are not identical.

A specific embodiment is shown in FIG. 1.

FIG. 1 shows an integrated circuit comprising a logic IC and an interface circuit.

FIG. 1 shows an integrated circuit 1 comprising a monolithically integrated logic IC 2 and a monolithically integrated interface circuit 3. Interface circuit 3 is connected to logic circuit 2 through a bus connection 4. In addition, interface circuit 3 has terminals 5 with which to communicate with the peripheral. To this extent, the arrangement of FIG. 1 matches the arrangement known from the initially referenced DE 102 43 684 A1. Interface circuit 3 is designed to be programmable in terms of its electrical properties. In particular, the bus interface 6 of interface circuit 3 is designed to be programmable as already described above. In addition, interface circuit 3 has monitoring modules 7 to monitor logic IC 2. Monitoring modules 7 are also located separately from logic IC 2 on interface circuit 3.

1. An integrated circuit comprising a logic IC and an interface circuit which is conductively connected to the logic IC,
wherein
the integrated circuit is formed from a monolithically integrated logic IC and a monolithically integrated interface circuit;
each interface circuit is designed to be programmable in terms of its electrical properties;
the interface circuit has a lower integration density than does the logic IC;
and the interface circuit has monitoring modules to monitor the logic IC.

2. The integrated circuit of claim 1, where the interface circuit has a voltage controller to regulate the operating voltage of the logic IC which is designed to be programmable in terms of its voltage level.

3. The integrated circuit of claim 1 or 2, where devices are provided to programmably modify the voltage level of the signals which are transferred between the logic IC and the interface circuit.

4. The integrated circuit claim 1, where the interface circuit has a bus interface, wherein the logic circuit of the bus interface is designed to be programmable.

5. A family of integrated circuits, wherein each circuit has a logic IC and an interface circuit which is conductively connected to the logic IC,
wherein
each integrated circuit is formed from a monolithically integrated logic IC and a monolithically integrated interface circuit;
each interface circuit is designed to be programmable in terms of its electrical properties;
each interface circuit has a lower integration density than does the logic IC;
wherein the logic ICs of the family of circuits have different integration densities, but all the interface circuits of the family of circuits have the same integration density;
and each interface circuit has monitoring modules to monitor the logic IC.

6. The family of integrated circuits of claim 5, where each interface circuit has a voltage controller to regulate the operating voltage of the logic IC which is programmable in terms of its voltage level.

7. The family of integrated circuits of claim 5, where devices for the programmable modification of the voltage level of the signals transferred between the logic IC and the interface circuit are provided for each circuit.

8. The family of integrated circuits of claim 5, where interface circuit has a bus interface, wherein the logic circuit of the bus interface is designed to be programmable.
